(19) United States
(12) Patent Application Publication
(10) Pub. No.: US 2026/0260840 A1
(43) Pub. Date: Sep. 3, 2026

(54) SYSTEM AND METHOD FOR IMAGE DISTURBANCE COMPENSATION

(71) Applicant: ASML Netherlands B.V., Veldhoven (NL)

(72) Inventors: Ying LUO, San Jose, CA (US); Zhonghua DONG, San Jose, CA (US)

(73) Assignee: ASML Netherlands B.V., Veldhoven (NL)

(21) Appl. No.: 18/878,606

(22) PCT Filed: Sep. 1, 2023
(86) PCT No.: PCT/EP2023/074093

§ 371 Date: Dec. 23, 2024

Related U.S. Application Data
(60) Provisional application No. 63/408,772, filed on Sep. 21, 2022.

(51) Int. Cl. H01J 37/22; H01J 37/26; H01J 37/28

(52) U.S. Cl. CPC H01J 37/222; H01J 37/265; H01J 37/28; H01J 2237/2826

(57) ABSTRACT

Systems, apparatuses, and methods include a generating a reference signal based on a power input for an imaging system; generating a scan signal indicating a scan of a sample; extracting, from an image generated from the scan, first and second disturbance data; generating a calibrated frequency, magnitude, and phase of the image disturbance using the extracted first and second disturbance data, the reference signal, and the scan signal; combining the calibrated frequency, magnitude, and phase of the image disturbance and the reference signal to generate a compensation signal; and using the compensation signal to control a plurality of deflection drivers used for manipulating charged particles to scan the sample.

### CROSS-REFERENCE TO RELATED APPLICATIONS

This application claims priority of U.S. application 63/408,772 which was filed on Sep. 21, 2022 and which is incorporated herein in its entirety by reference.

### FIELD

The description herein relates to the field of inspection systems, and more particularly to systems for image disturbance compensation.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused on locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for image disturbance compensation. In some embodiments, systems and methods may include generating a reference signal based on a power input for an imaging system; generating a scan signal indicating a scan of a sample; extracting, from an image generated from the scan, first and second disturbance data; generating a calibrated frequency, magnitude, and phase of the image disturbance using the extracted first and second disturbance data, the reference signal, and the scan signal; combining the calibrated frequency, magnitude, and phase of the image disturbance and the reference signal to generate a compensation signal; and using the compensation signal to control a plurality of deflection drivers used for manipulating charged particles to scan the sample.

In some embodiments, systems and methods may include generating a reference signal based on a power input for an imaging system; generating a scan signal indicating a scan of a sample; extracting, from an image generated from the scan, a frequency profile of an image disturbance; generating a calibrated signal based on the reference signal and the extracted frequency profile; generating a compensation signal using the calibrated signal and the reference signal; transforming image coordinates associated with the compensation signal into deflection driver coordinates; and using the deflection driver coordinates of the compensation signal to control a plurality of deflection drivers used for manipulating charged particles to scan the sample.

### BRIEF DESCRIPTION OF THE DRAWINGS

FIG. 1 is a schematic diagram illustrating an exemplary electron beam inspection (EBI) system, consistent with embodiments of the present disclosure.

FIG. 2A is a schematic diagram illustrating an exemplary multi-beam system that is part of the exemplary charged particle beam inspection system of FIG. 1, consistent with embodiments of the present disclosure.

FIG. 2B is a schematic diagram illustrating an exemplary single-beam system that is part of the exemplary charged particle beam inspection system of FIG. 1, consistent with embodiments of the present disclosure.

FIG. 3A is a plan view of an illustrative embodiment of a deflection structure implemented in an electron beam inspection system, consistent with embodiments of the present disclosure.

FIG. 3B is a cross-sectional view of an illustrative embodiment of a deflection system that may be used in an electron beam inspection system, consistent with embodiments of the present disclosure.

FIG. 4A is a diagrammatic representation of a driver, consistent with embodiments of the present disclosure.

FIG. 4B is a diagrammatic representation of a plurality of drivers, consistent with embodiments of the present disclosure.

FIG. 5 is a schematic diagram of an exemplary system for image disturbance compensation, consistent with embodiments of the present disclosure.

FIG. 6A and FIG. 6B exemplary generated images of line patterns on a sample, consistent with embodiments of the present disclosure.

FIG. 7 is a flowchart illustrating an exemplary process of image disturbance compensation, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly, and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

System power line induced image disturbances are one of the main critical sources of image disturbance in inspection systems. Specifically, periodic electric-magnetic disturbances (e.g., disturbances on an image with a periodic pattern) from system power lines is a critical source of image disturbance. These power line induced image disturbances may be caused by any electrical module, cable, rack through signals, grounding, electric-magnetic fields in space, etc. and should be compensated for to generate accurate images (e.g., during inspection).

Typical inspection systems, however, suffer from constraints. Typical inspection systems may use pure software-based methods to compensate for image disturbances. However, pure software-based compensation methods are unreliable and insufficient because they can only recognize or characterize some image disturbance patterns, but fail to recognize or characterize other image disturbance patterns (e.g., they cannot compensate for image disturbances for dots, holes, etc.).

Some of the disclosed embodiments provide systems and methods that address some or all of these disadvantages by using hardware-based methods to compensate for image disturbances. The disclosed embodiments may include extracting a magnitude and a phase of an image disturbance from an image, generating a compensation signal, and providing the compensation signal to deflection drivers, thereby compensating for power line induced image disturbances of any type of pattern.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

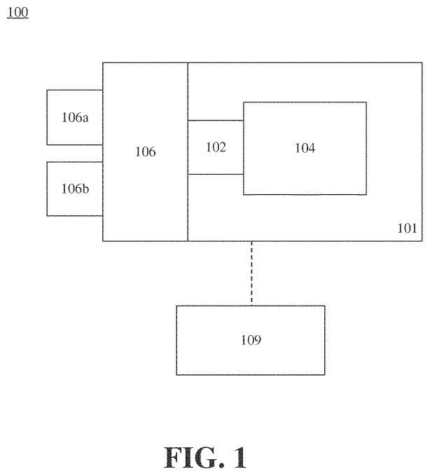

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries and adapting to different throughputs and resolution requirements.

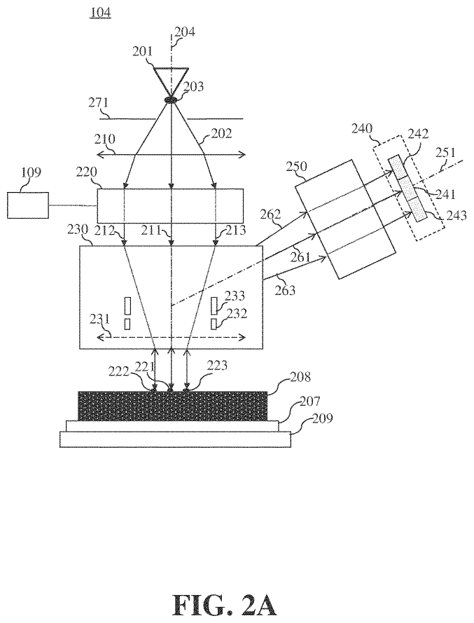

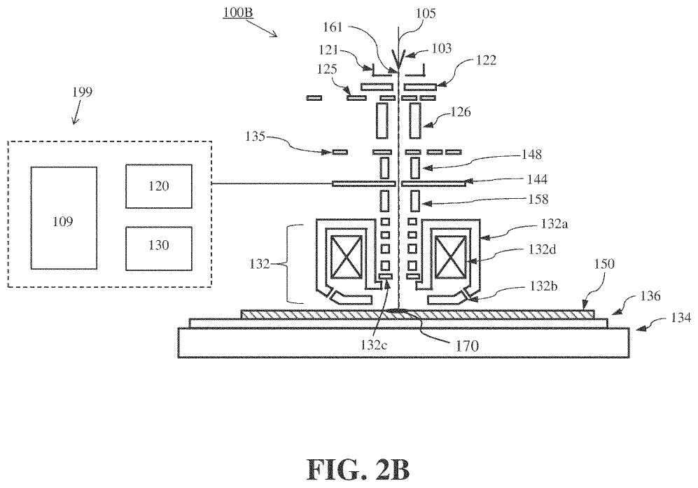

Reference is now made to FIG. 2A, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2A shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2A). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2A shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

For example, as shown in FIG. 2B, an electron beam tool 100B (also referred to herein as apparatus 100B) may be a single-beam inspection tool that is used in EBI system 10, consistent with embodiments of the present disclosure. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150.

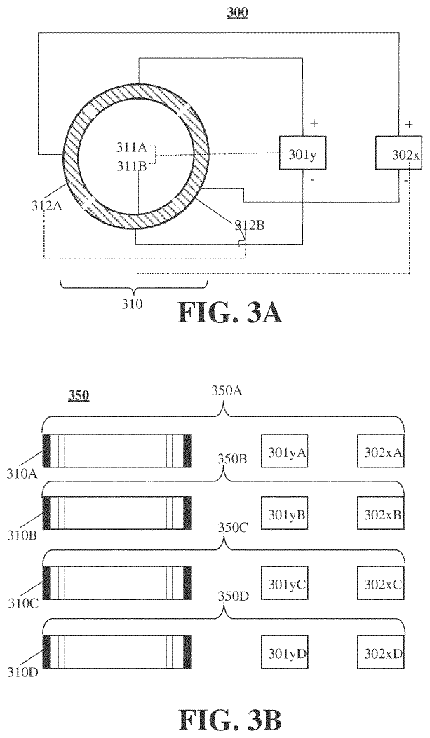

Reference is now made to FIG. 3A, which shows a plan view of an illustrative embodiment of a deflection structure 300 (e.g., deflection scanning unit 232 of FIG. 2A, deflector 132c of FIG. 2B) implemented in an electron beam inspection system (e.g., EBI system 100 of FIG. 1), consistent with embodiments of the present disclosure. The electron beam inspection system may include a single beam or a multi-beam system. In some embodiments, deflection structure 400 can be one of several deflection structures to be implemented in a scanning deflection system of an electron beam inspection system. Deflection structure 400 can be used to manipulate an electron beam.

A deflection system may include a deflection structure and driver system. A deflection structure may include a multipole structure. As shown in FIG. 3A, deflection structure 300 includes a multi-pole structure 310, a first driver system 301y, and a second driver system 302x. The multi-pole structure 310 includes a first set of opposing electrodes 311A-B and a second set of opposing electrodes 312A-B that can be configured to deflect the electron beam in each deflection direction (such as the x-direction or y-direction) based on output states applied to each set. The output states may correspond to voltages applied to the electrodes. The multi-pole structure 310, comprising sets of electrodes 311A-B and 312A-B, can function as a dynamic deflector based on the voltages applied to the electrodes 311A-B and 312A-B. For example, when first driver system 301y applies 0V to electrodes 311A and 311B, second driver system 302x applies V1 to electrode 312A and −V1 to electrode 312B, the electron beam is deflected in a x-direction. By way of further example, when first driver system 301y applies V2 to electrode 311A and −V2 to electrode 311B, and second driver system 302x applies 0V to electrodes 312A and 312B, the electron beam is deflected in a y-direction. When V1 and V2 increase, the angles of deflection of the electron beam increases as well. FIG. 3A shows four electrodes configured in multi-pole structure 310 as an example, and it is appreciated that multi-pole structure 310 can be configured to form more than four electrodes. Moreover, FIG. 3A shows two sets of opposing electrodes 311A-B and 312A-B configured in multi-pole structure 310 as an example, and it is appreciated that multi-pole structure 310 can be configured to form any number of sets of opposing electrodes (including one).

In some embodiments, sets of electrodes 311A-B and 312A-B can be formed in a substrate and include multiple beam manipulators in the substrate. For example, each beam manipulator can be electrically isolated from other beam manipulators by a circular trench filled with isolating material (e.g., such as CVD oxide). Within the circular area, the manipulator can be formed, for example, by etching a deflector hole and any isolating trenches between the electrodes and by sputtering a metal layer over the places where electrodes should be formed. The metal layers may form sets of electrodes 311A-B and 312A-B and some of the layers can be used for a first set of electrodes and other layers can be used for a second set of electrodes.

First driver system 301y is electrically connected to the first set of opposing electrodes 311A-B and configured to provide a plurality of discrete output states to the first set of opposing electrodes 311A-B, and second driver system 302x is electrically connected to the second set of opposing electrodes 312A-B and configured to provide a plurality of discrete output states to the second set of opposing electrodes 312A-B. As discussed above with respect to the multi-pole structure 310, each of the driver systems 301y and 302x is configured to enable a set of opposing electrodes (such as 311A-B and 312A-B) to deflect the electron beam in a direction by providing a plurality of discrete output states to the corresponding set of opposing electrodes. Each of the driver systems 301y and 302x may include a plurality of power supplies and a plurality of switches. The switches may refer to active devices operating in switch mode.

A power supply may be configured to provide a plurality of discrete output states. Or, each of a plurality of power supplies can be configured to provide a discrete output state. For example, driver 301y can be configured with a power supply that provides −100V, 0V, and +100V. By way of further example, driver 301y can be configured with a power supply that provides −100V, −50V, 0V, +50V, and +100V.

The plurality of switches can be configured by a controller and transmit the incoming discrete output state from a power supply to the corresponding set of opposing electrodes. A controller (e.g., controller 109 of FIG. 1) may transmit digital signals to apply the digital signals to turn on or off switches to transmit the incoming discrete output state or block the output state. For example, three switches may connect three tap points associated with a power supply and a first set of opposing electrodes, and a controller may transmit digital signals to select one of the three switches to transmit a desired output state from the power supply corresponding to the selected switch. The plurality of switches can be MOS drivers enabling a fast transition of output states.

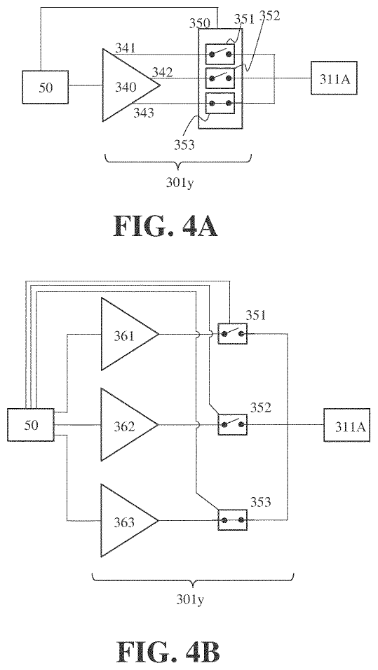

Reference is now made to FIG. 4A, which shows a diagrammatic representation of a driver (such as driver system 301y), consistent with embodiments of the disclosure. Driver system 301y may be configured to provide a plurality of output states. The output states may correspond to, for example, −100V, 0V, and 100V. Driver system 301y may include a multi-output driver 340. Multi-output driver 340 may have a first output 341, a second output 342, and a third output 343. Outputs 341, 342, 343 may correspond to −100V, 0V, and 100V, respectively. Driver system 301y may also include a switch unit 350. Switch unit 350 may include a plurality of separate switches. Switch unit 350 may be configured to operate such that only one connection is allowed at a time. Switch unit 350 includes a first switch 351, a second switch 352, and a third switch 353. In the state shown in FIG. 4A, only third switch 353 is connected. Thus, the output to electrode 311A may be that provided by third output 343.

Control signals may be provided to components of driver system 301y. As shown in FIG. 4A, controller 50 may be configured to control driver system 301y. Controller 50 may be connected to multi-output driver 340 and may be configured to instruct multi-output driver 340 to operate. Controller 50 may be connected to switch unit 350 and may be configured to instruct switch unit 350 to operate. For example, controller 50 may instruct multi-output driver 340 to supply power and instruct switch unit 350 to select one of switches 351, 352, 353 to be connected so that an output state is provided to electrode 311A.

In some embodiments, each of first driver system 301y and a second driver system 302x may comprise a plurality of physical drivers. Each of the plurality of physical drivers may comprise a power supply providing a discrete output and a switch similar to that described above. The physical driver may be configured to provide a discrete output state to corresponding electrodes (such as electrodes 311A-B and 312A-B).

Reference is now made to FIG. 4B, which shows a diagrammatic representation of a plurality of drivers, consistent with embodiments of the disclosure. Driver system 301y may be configured to provide a plurality of output states by providing separate drivers that each produce an output. Each separate driver may be configured to provide its own output. Driver system 301y may include a first driver 361, a second driver 362, and a third driver 363. Each of drivers 361, 362, and 363 may be configured to supply power at a predetermined output. Drivers 361, 362, and 363 are connected to switches 351, 352, and 353, respectively. Controller 50 may be configured to separately operate switches 351, 352, and 353. Controller 50 may be configured to separately operate drivers 361, 362, and 363. Controller 50 may be configured to operate switches so that only one switch is connected at a time. In the state shown in FIG. 4B, only third switch 353 is connected. Thus, output to electrode 311A may be provided only by third driver 363.

Reference is now made to FIG. 3B, which shows a cross-sectional view of an illustrative embodiment of a deflection system 350 that may be used in an electron beam inspection system, consistent with embodiments of the present disclosure. Deflection system 350 includes deflection structures 350A-D, with each structure in a corresponding layer. Each deflection structure 350A-D comprises a manipulator or multi-pole structure (310A-D) and a plurality of driver systems (301yA-D and 302xA-D). In some embodiments, the plurality of driver systems (301yA-D and 302xA-D) and the multi-pole structure (310A-D) can be implemented in separate layers. Deflection structures 350A-D can function as deflectors implemented in deflection scanning unit 232 of FIG. 2A or deflector 132c of FIG. 2B, among others. Each of the plurality of driver systems (301yA-D and 302xA-D) is electrically connected to a set of opposing electrodes implemented in the multi-pole structure (310A-D) and configured to provide a plurality of discrete output states to the set of opposing electrodes implemented in the multi-pole structure. For example, driver 301yA may be electrically connected to a set of opposing electrodes implemented in multi-pole structure 310A and driver 302xA may be electrically connected to another set of opposing electrodes in multi-pole structure 310A. Deflection structures 350A-D and deflection structure 300 (depicted in FIG. 3A) share the same functionalities, such as manipulating an electron beam. Multi-pole structures 310A-D and multi-pole structure 310 (depicted in FIG. 3A) share the same functionalities to deflect an electron beam in a direction when provided with output states from driver systems. Driver systems 301A-D and 302A-D and driver systems 301y and 302x (depicted in FIG. 3A) share the same functionalities providing discrete output states to multi-pole structures to deflect the beam. Moreover, while FIG. 3B shows four layers of deflection structures 350A-D, it is appreciated that deflection structures can be implemented in any number of layers.

While in the embodiments of FIG. 3B each layer of the multiple layers (e.g., 310A-D) is sized to have substantially the same dimensions, the size of each layer can be determined by physical dimensions (such as a length, an inner diameter, and an outer diameter) of the electrodes implemented in the layer and corresponds to the deflection angles. For example, a deflection structure (such as 350A-D) in each layer may deflect an electron beam in a substantially identical deflection angle when driver systems 301yA-D and 302xA-D provide substantially identical output states to electrodes of multi-pole structures 310A-D. In another example, a deflection structure (such as 350A-D) in each layer may deflect an electron beam in a different deflection angle when its corresponding driver system (e.g., 301yA-D and 302xA-D) provides different output states to electrodes of its corresponding multi-pole structure (e.g., 310A-D).

In some embodiments, one or more of multiple layers (such as a layer including deflection structures 350D) can be implemented with a driver system comprising a linear amplifier with limited output voltage swing to provide finer deflection control by enabling the embodiments to provide high resolution output voltage to electrodes in one layer of the multiple layer structure. For example, when a scanning deflection system in an electron beam inspection system is configured to deflect an electron beam with the deflection equivalent to applying 155V to a single conventional multi-pole structure of the same size as one of 310A-D, a controller may configure switches connected to a multi-pole structure (such as one of 350A-C) to transmit 50V from a discrete power supply implemented in each deflection structure. Thus, the electrode pairs in three of the four multi-pole structures in FIG. 3B may be connected to −25V and +25V respectively. To achieve the remaining part of deflection equivalent to applying 5V to a conventional multi-pole structure of the same size, the controller may configure a deflection structures (such as 450D) implemented with the aforementioned linear amplifier supplying −2.5V and 2.5V to the multi-pole structure. However, since this linear amplifier has a much more limited range than would be needed with existing deflectors, it may be much easier to implement, may be faster, may have lower power, etc. as compared to one used with an existing deflector.

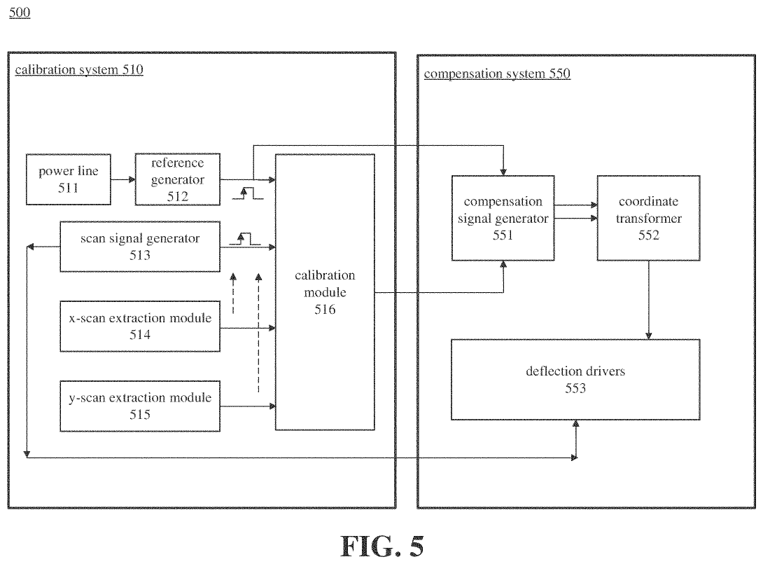

Reference is now made to FIG. 5, which illustrates a schematic diagram of an exemplary system 500 for image disturbance compensation, consistent with embodiments of the present disclosure. System 500 may be a part of EBI system 100 of FIG. 1, electron beam tool 104 of FIG. 2A, or electron beam tool 100B of FIG. 2B.

In some embodiments, system 500 may include a calibration system 510 and a compensation system 550. While different modules or components are shown in calibration system 510 and in compensation system 550, it should be understood that modules and components of calibration system 510 and compensation system 550 are not limited to the configuration shown in FIG. 5.

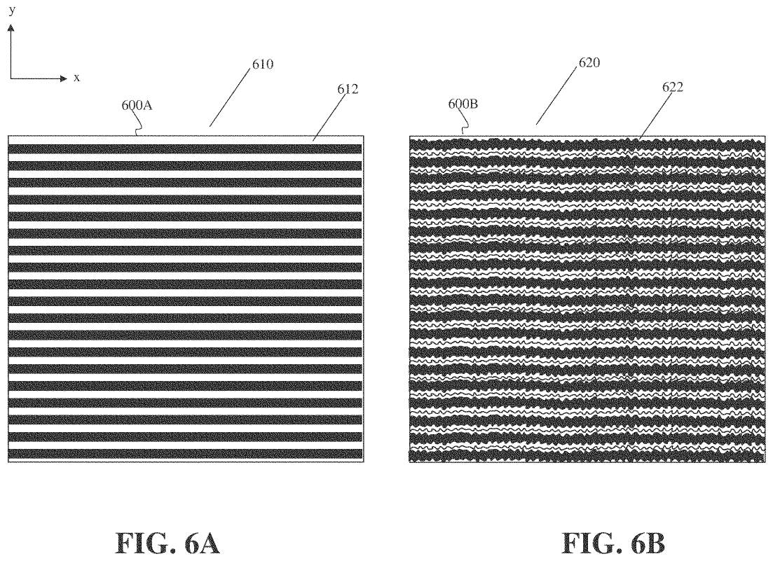

In some embodiments, calibration system 510 may include a power line 511 connected to a power source of system 500 (e.g., an imaging system). In some embodiments, calibration system 510 may include a reference generator 512, which may generate a reference signal based on a power input from power line 511. Calibration system 510 may include a scan signal generator 513, which may generate a signal indicating a start of a scan of a sample in system 500. For example, the generated scan signal may be transmitted to deflection drivers 553 (e.g., deflection drivers of deflection scanning unit 232 of FIG. 2A; deflection drivers of deflector 132c of FIG. 2B; first driver system 301y of FIGS. 3A, 4A, and 4B; second driver system 302x of FIG. 3A; driver systems 301yA-D of FIG. 3B; driver systems 302xA-D of FIG. 3B) of compensation system 550 to initiate scanning and generation of an image in system 500. In some embodiments, the generated image may be an image of a sample with a line pattern, but the line pattern in the generated image may include disturbances with a periodic pattern induced by power line 511 (e.g., line pattern 620 of FIG. 6B). For example, the disturbance pattern of the feature on the generated image may be characterized by a phase and a magnitude, rather than a straight line (e.g., line pattern 610 of FIG. 6A).

In some embodiments, calibration system 510 may include an x-scan extraction module 514 and a y-scan extraction module 515. X-scan extraction module 514 may extract a magnitude and a phase in a first direction (e.g., “x” direction) of the disturbance pattern in the generated image while module y-scan extraction module 515 may extract a magnitude and a phase in a second direction (e.g., “y” direction) of the disturbance pattern in the generated image. In some embodiments, module x-scan extraction module 514 and module y-scan extraction module 515 may extract the phase in the first and second directions of the disturbance pattern using an image vibration analysis on the disturbance pattern of the image. In some embodiments, the image vibration analysis may include characterizing the disturbance pattern of the image (e.g., recognizing the shape or pattern characteristics of the disturbance pattern of the image). In some embodiments, the image vibration analysis may include applying an image line pattern edge extraction algorithm to obtain an image vibration signal for analysis in a time domain and in a frequency domain.

In some embodiments, calibration system 510 may include a calibration module 516. Calibration module 516 may combine the reference signal transmitted from reference generator 512, the scan signal transmitted from scan signal generator 513, the first direction magnitude and phase transmitted from x-scan extraction module 514, and the second direction magnitude and phase from module y-scan extraction module 515 to generate a calibrated signal. In some embodiments, the calibrated signal may be generated by aligning the scan signal with the reference signal to obtain a phase relationship between the scan signal and the reference signal. In some embodiments, the calibrated signal may include a frequency, magnitude, and phase of the disturbance pattern as compared to the reference signal (e.g., the calibrated signal may include a difference in frequency, magnitude, and phase between the disturbance pattern and the reference signal). In some embodiments, the calibrated signal may include a frequency, magnitude, and phase of the disturbance pattern in a first direction and a frequency, magnitude, and phase of the disturbance pattern in a second direction.

In some embodiments, compensation system 550 may include a compensation signal generator 551, which may generate a compensation signal by combining the calibrated signal transmitted from calibration module 516 and the reference signal transmitted from reference generator 512. The generated compensation signal may include image coordinates for adjusting the generated image in the first direction and image coordinates for adjusting the generated image in the second direction.

In some embodiments, compensation system 550 may include a coordinate transformer 552, which may transform the image coordinates associated with the compensation signal transmitted from compensation signal generator 551 into deflection driver coordinates. In some embodiments, coordinate transformer 552 may transmit the compensation signal, including the deflection driver coordinates, to deflection drivers 553. The compensation signal may be used to control deflection drivers 553 used for manipulating charged particles to scan a sample for generating an image with reduced image disturbance based on the power input (e.g., generate an image without the image disturbance). In some embodiments, the deflection driver coordinates may include coordinates in the first direction and coordinates in the second direction. In some embodiments, system 500 may generate a calibration signal and a compensation signal once for some period of time (e.g., for some number of sample scans).

Reference is now made to FIG. 6A and FIG. 6B, exemplary generated images of line patterns on a sample, consistent with embodiments of the present disclosure. Generated image 600A of FIG. 6A and generated image 600B of FIG. 6A may be a top view of a sample, with a first direction “x” and a second direction “y.”

As shown in FIG. 6A, generated image 600A of line pattern 610 may include lines 612, which have no power line induced image disturbances. In contrast, FIG. 6B shows generated image 600B of line pattern 620, which may include lines 622. Lines 622 include power line induced image disturbances with a periodic pattern. For example, the disturbance pattern of lines 622 in generated image 600B may be characterized by phases and magnitudes, rather than a straight line.

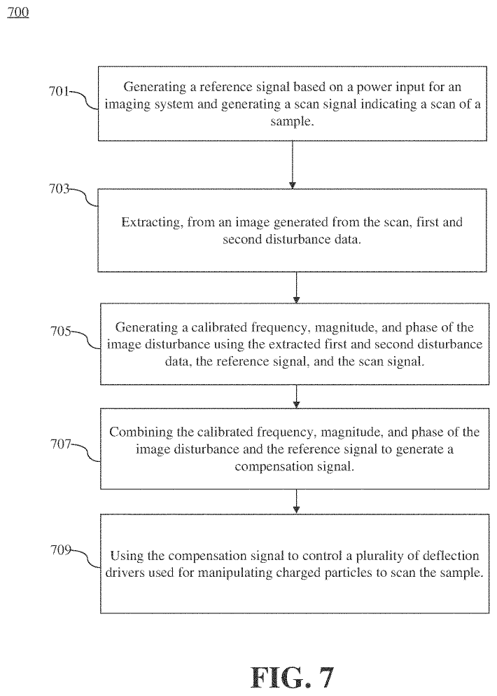

Reference is now made to FIG. 7, a flowchart illustrating an exemplary process 700 of image disturbance compensation, consistent with embodiments of the present disclosure. The steps of method 700 can be performed by a system (e.g., system 500 of FIG. 5) executing on or otherwise using the features of a computing device (e.g., controller 109 of FIG. 1, system 500 of FIG. 5, or any components thereof) for purposes of illustration. It is appreciated that the illustrated method 700 can be altered to modify the order of steps and to include additional steps that may be performed by the system.

At step 701, a component (e.g., reference generator 512 of FIG. 5) may generate a reference signal based on a power input from a power line (e.g., power line 511 of FIG. 5) and a component (e.g., scan signal generator 513 of FIG. 5) may generate a signal indicating a scan of a sample (e.g., in system 500 of FIG. 5). For example, the generated scan signal may be transmitted to deflection drivers (deflection drivers of deflection scanning unit 232 of FIG. 2A; deflection drivers of deflector 132c of FIG. 2B; first driver system 301y of FIGS. 3A, 4A, and 4B; second driver system 302x of FIG. 3A; driver systems 301yA-D of FIG. 3B; driver systems 302xA-D of FIG. 3B) to initiate scanning of a sample for generating an image. In some embodiments, the generated image may be an image of a sample with a line pattern, but the line pattern in the generated image may include disturbances with a periodic pattern induced by the power line. For example, the disturbance pattern of the feature on the generated image may be characterized by a phase and a magnitude, rather than a straight line.

At step 703, a component (e.g., x-scan extraction module 514 and y-scan extraction module 515 of FIG. 5) may extract, from an image generated from the scan, first and second disturbance data. In some embodiments, the first disturbance data may include a magnitude and a phase in a first direction (e.g., “x” direction) of the disturbance pattern in the generated image and the second disturbance data may include a magnitude and a phase in a second direction (e.g., “y” direction) of the disturbance pattern in the generated image. In some embodiments, the component may extract the phase in the first and second directions of the disturbance pattern using an image vibration analysis on the disturbance pattern of the image. In some embodiments, the image vibration analysis may include characterizing the disturbance pattern of the image (e.g., recognizing the shape or pattern characteristics of the disturbance pattern of the image). In some embodiments, the image vibration analysis may include applying an image line pattern edge extraction algorithm to obtain an image vibration signal for analysis in a time domain and in a frequency domain.

At step 705, a component (e.g., calibration module 516 of FIG. 5) may combine the reference signal, the scan signal, the first direction magnitude and phase, and the second direction magnitude and phase to generate a calibrated signal. In some embodiments, the calibrated signal may be generated by aligning the scan signal with the reference signal to obtain a phase relationship between the scan signal and the reference signal. In some embodiments, the calibrated signal may include a frequency, magnitude, and phase of the disturbance pattern as compared to the reference signal (e.g., the calibrated signal may include a difference in frequency, magnitude, and phase between the disturbance pattern and the reference signal). In some embodiments, the calibrated signal may include a frequency, magnitude, and phase of the disturbance pattern in a first direction and a frequency, magnitude, and phase of the disturbance pattern in a second direction.

At step 707, a component (e.g., compensation signal generator 551 of FIG. 5) may generate a compensation signal by combining the calibrated and the reference signal transmitted. The generated compensation signal may include image coordinates for adjusting the generated image in the first direction and image coordinates for adjusting the generated image in the second direction.

At step 709, a component (e.g., coordinate transformer 552 of FIG. 5) may transform the image coordinates associated with the compensation signal into deflection driver coordinates and use the compensation signal to control a plurality of deflection drivers used for manipulating charged particles to scan the sample. In some embodiments, the deflection driver coordinates may include coordinates in the first direction and coordinates in the second direction.

A non-transitory computer readable medium may be provided that stores instructions for a processor of a controller (e.g., controller 109 of FIG. 1) for controlling the electron beam tool or other systems (e.g., calibration system 510 of FIG. 5, compensation system 550 of FIG. 5) of other systems and servers, or components thereof, consistent with embodiments in the present disclosure. These instructions may allow the one or more processors to carry out image disturbance compensation, image processing, data processing, beamlet scanning, graphical display, operations of a charged particle beam apparatus, or another imaging device, or the like. In some embodiments, the non-transitory computer readable medium may be provided that stores instructions for a processor to perform the steps of process 700. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method comprising:
generating a reference signal based on a power input for an imaging system;
generating a scan signal indicating a scan of a sample;
extracting, from an image generated from the scan, first and second disturbance data;
generating a calibrated frequency, magnitude, and phase of the image disturbance using the extracted first and second disturbance data, the reference signal, and the scan signal;
combining the calibrated frequency, magnitude, and phase of the image disturbance and the reference signal to generate a compensation signal; and
using the compensation signal to control a plurality of deflection drivers used for manipulating charged particles to scan the sample.
2. The method of clause 1, wherein the image disturbance comprises a pattern of a feature in the generated image.
3. The method of clause 2, wherein generating the calibrated frequency, magnitude, and phase of the image disturbance comprises characterizing the pattern.

4. The method of any one of clauses 2-3, wherein the pattern is periodic.
5. The method of any one of clauses 1-4, wherein manipulating charged particles to scan the sample reduces image disturbance caused by the power input.
6. The method of any one of clauses 1-5, wherein the first disturbance data comprises a magnitude and a phase of an image disturbance in a first direction and the second disturbance data comprises a magnitude and a phase of an image disturbance in a second direction
7. The method of clause 6, wherein the compensation signal comprises image coordinates of the generated image in the first direction and image coordinates of the generated image in the second direction, wherein the image coordinates of the generated image lack coordinates for controlling the plurality of deflection drivers.
8. The method of clause 7, further comprising transforming the image coordinates of the compensation signal into deflection driver coordinates to control the plurality of deflection drivers.
9. A method comprising:
generating a reference signal based on a power input for an imaging system;
generating a scan signal indicating a scan of a sample;
extracting, from an image generated from the scan, a frequency profile of an image disturbance;
generating a calibrated signal based on the reference signal and the extracted frequency profile;
generating a compensation signal using the calibrated signal and the reference signal;
transforming image coordinates associated with the compensation signal into deflection driver coordinates; and
using the deflection driver coordinates of the compensation signal to control a plurality of deflection drivers used for manipulating charged particles to scan the sample.
10. The method of clause 9, wherein the image disturbance comprises a pattern of a feature in the generated image.
11. The method of clause 10, wherein generating the calibrated signal comprises characterizing the pattern.

12. The method of any one of clauses 10-11, wherein the pattern is periodic.
13. The method of any one of clauses 9-12, wherein manipulating charged particles to scan the sample reduces image disturbance caused by the power input.
14. The method of any one of clauses 9-13, wherein the frequency profile of the image disturbance comprises a magnitude and a phase of an image disturbance in a first direction and a magnitude and a phase of an image disturbance in a second direction
15. The method of clause 14, wherein the compensation signal comprises image coordinates of the generated image in the first direction and image coordinates of the generated image in the second direction, wherein the image coordinates of the generated image lack coordinates for controlling the plurality of deflection drivers.

16. The method of clause 15, further comprising transforming the image coordinates of the compensation signal into deflection driver coordinates to control the plurality of deflection drivers.
17. A non-transitory computer readable medium including a set of instructions that is executable by one or more processors of an apparatus to cause the apparatus to perform a method comprising:
generating a reference signal based on a power input for an imaging system;
generating a scan signal indicating a scan of a sample;
extracting, from an image generated from the scan, first and second disturbance data;
generating a calibrated frequency, magnitude, and phase of the image disturbance using the extracted first and second disturbance data, the reference signal, and the scan signal;
combining the calibrated frequency, magnitude, and phase of the image disturbance and the reference signal to generate a compensation signal; and
using the compensation signal to control a plurality of deflection drivers used for manipulating charged particles to scan the sample.
18. The non-transitory computer readable medium of clause 17, wherein the image disturbance comprises a pattern of a feature in the generated image.
19. The non-transitory computer readable medium of clause 18, wherein generating the calibrated frequency, magnitude, and phase of the image disturbance comprises characterizing the pattern.

20. The non-transitory computer readable medium of any one of clauses 18-19, wherein the pattern is periodic.
21. The non-transitory computer readable medium of any one of clauses 17-20, wherein manipulating charged particles to scan the sample reduces image disturbance caused by the power input.
22. The non-transitory computer readable medium of any one of clauses 17-21, wherein the first disturbance data comprises a magnitude and a phase of an image disturbance in a first direction and the second disturbance data comprises a magnitude and a phase of an image disturbance in a second direction
23. The non-transitory computer readable medium of clauses 22, wherein the compensation signal comprises image coordinates of the generated image in the first direction and image coordinates of the generated image in the second direction, wherein the image coordinates of the generated image lack coordinates for controlling the plurality of deflection drivers.
24. The non-transitory computer readable medium of clause 23, wherein the set of instructions that is executable by at least one processor of a computing device to cause the computing device to further perform transforming the image coordinates of the compensation signal into deflection driver coordinates to control the plurality of deflection drivers. 25. A non-transitory computer readable medium including a set of instructions that is executable by one or more processors of an apparatus to cause the apparatus to perform a method comprising:
generating a reference signal based on a power input for an imaging system;
generating a scan signal indicating a scan of a sample;
extracting, from an image generated from the scan, a frequency profile of an image disturbance;
generating a calibrated signal based on the reference signal and the extracted frequency profile;
generating a compensation signal using the calibrated signal and the reference signal;
transforming image coordinates associated with the compensation signal into deflection driver coordinates; and
using the deflection driver coordinates of the compensation signal to control a plurality of deflection drivers used for manipulating charged particles to scan the sample.
26. The non-transitory computer readable medium of clause 25, wherein the image disturbance comprises a pattern of a feature in the generated image.
27. The non-transitory computer readable medium of clause 26, wherein generating the calibrated signal comprises characterizing the pattern.
28. The non-transitory computer readable medium of any one of clauses 26-27, wherein the pattern is periodic.
29. The non-transitory computer readable medium of any one of clauses 25-28, wherein manipulating charged particles to scan the sample reduces image disturbance caused by the power input.
30. The non-transitory computer readable medium of any one of clauses 25-29, wherein the frequency profile of the image disturbance comprises a magnitude and a phase of an image disturbance in a first direction and a magnitude and a phase of an image disturbance in a second direction
31. The non-transitory computer readable medium of clause 30, wherein the compensation signal comprises image coordinates of the generated image in the first direction and image coordinates of the generated image in the second direction, wherein the image coordinates of the generated image lack coordinates for controlling the plurality of deflection drivers.
32. The non-transitory computer readable medium of clause 31, wherein the set of instructions that is executable by at least one processor of a computing device to cause the computing device to further perform transforming the image coordinates of the compensation signal into deflection driver coordinates to control the plurality of deflection drivers.
33. A system comprising:
one or more processors configured to execute instructions to cause the system to perform:
generate a reference signal based on a power input for an imaging system;
generate a scan signal indicating a scan of a sample;
extract, from an image generated from the scan, first and second disturbance data;
generate a calibrated frequency, magnitude, and phase of the image disturbance using the extracted first and second disturbance data, the reference signal, and the scan signal;
combine the calibrated frequency, magnitude, and phase of the image disturbance and the reference signal to generate a compensation signal; and
use the compensation signal to control a plurality of deflection drivers used for manipulating charged particles to scan the sample.
34. The system of clause 33, wherein the image disturbance comprises a pattern of a feature in the generated image.
35. The system of clause 34, wherein generating the calibrated frequency, magnitude, and phase of the image disturbance comprises characterizing the pattern.
36. The system of any one of clauses 34-35, wherein the pattern is periodic.
37. The system of any one of clauses 33-36, wherein manipulating charged particles to scan the sample reduces image disturbance caused by the power input.
38. The system of any one of clauses 33-37, wherein the first disturbance data comprises a magnitude and a phase of an image disturbance in a first direction and the second disturbance data comprises a magnitude and a phase of an image disturbance in a second direction
39. The system of clause 38, wherein the compensation signal comprises image coordinates of the generated image in the first direction and image coordinates of the generated image in the second direction, wherein the image coordinates of the generated image lack coordinates for controlling the plurality of deflection drivers.
40. The system of clause 39, wherein the one or more processors are configured to execute instructions to cause the system to further perform: transform the image coordinates of the compensation signal into deflection driver coordinates to control the plurality of deflection drivers.
41. A system comprising:
one or more processors configured to execute instructions to cause the system to perform:
generate a reference signal based on a power input for an imaging system;
generate a scan signal indicating a scan of a sample;
extract, from an image generated from the scan, a frequency profile of an image disturbance;
generate a calibrated signal based on the reference signal and the extracted frequency profile;
generate a compensation signal using the calibrated signal and the reference signal;
transform image coordinates associated with the compensation signal into deflection driver coordinates; and
use the deflection driver coordinates of the compensation signal to control a plurality of deflection drivers used for manipulating charged particles to scan the sample.
42. The system of clause 41, wherein the image disturbance comprises a pattern of a feature in the generated image.
43. The system of clause 42, wherein generating the calibrated signal comprises characterizing the pattern.
44. The system of any one of clauses 42-43, wherein the pattern is periodic.
45. The system of any one of clauses 41-44, wherein manipulating charged particles to scan the sample reduces image disturbance caused by the power input.
46. The system of any one of clauses 41-45, wherein the frequency profile of the image disturbance comprises a magnitude and a phase of an image disturbance in a first direction and a magnitude and a phase of an image disturbance in a second direction.
47. The system of clause 46, wherein the compensation signal comprises image coordinates of the generated image in the first direction and image coordinates of the generated image in the second direction, wherein the image coordinates of the generated image lack coordinates for controlling the plurality of deflection drivers.
48. The system of clause 47, wherein the one or more processors configured to execute instructions to cause the system to perform:
transform the image coordinates of the compensation signal into deflection driver coordinates to control the plurality of deflection drivers.

It will be appreciated that the embodiments of the present disclosure are not limited to the exact construction that has been described above and illustrated in the accompanying drawings, and that various modifications and changes may be made without departing from the scope thereof.

1. A non-transitory computer readable medium including a set of instructions that is executable by one or more processors of an apparatus to cause the apparatus to perform a method comprising:
generating a reference signal based on a power input for an imaging system;
generating a scan signal indicating a scan of a sample;
extracting, from an image generated from the scan, first and second disturbance data;
generating a calibrated frequency, magnitude, and phase of image disturbance using the extracted first and second disturbance data, the reference signal, and the scan signal;
combining the calibrated frequency, magnitude, and phase of the image disturbance and the reference signal to generate a compensation signal; and
using the compensation signal to control a plurality of deflection drivers used for manipulating charged particles to scan the sample.

2. The non-transitory computer readable medium of claim 1, wherein the image disturbance comprises a pattern of a feature in the generated image.

3. The non-transitory computer readable medium of claim 2, wherein generating the calibrated frequency, magnitude, and phase of the image disturbance comprises characterizing the pattern.

4. The non-transitory computer readable medium of claim 2, wherein the pattern is periodic.

5. The non-transitory computer readable medium of claim 1, wherein manipulating charged particles to scan the sample reduces image disturbance caused by the power input.

6. The non-transitory computer readable medium of claim 1, wherein the first disturbance data comprises a magnitude and a phase of an image disturbance in a first direction and the second disturbance data comprises a magnitude and a phase of an image disturbance in a second direction.

7. The non-transitory computer readable medium of claim 6, wherein the compensation signal comprises image coordinates of the generated image in the first direction and image coordinates of the generated image in the second direction, wherein the image coordinates of the generated image lack coordinates for controlling the plurality of deflection drivers.

8. The non-transitory computer readable medium of claim 7, wherein the set of instructions that is executable by at least one processor of a computing device to cause the computing device to further perform transforming the image coordinates of the compensation signal into deflection driver coordinates to control the plurality of deflection drivers.

9. A system comprising:
one or more processors configured to execute instructions to cause the system to perform:
generate a reference signal based on a power input for an imaging system;
generate a scan signal indicating a scan of a sample;
extract, from an image generated from the scan, first and second disturbance data;
generate a calibrated frequency, magnitude, and phase of image disturbance using the extracted first and second disturbance data, the reference signal, and the scan signal;
combine the calibrated frequency, magnitude, and phase of the image disturbance and the reference signal to generate a compensation signal; and
use the compensation signal to control a plurality of deflection drivers used for manipulating charged particles to scan the sample.

10. The system of claim 9, wherein the image disturbance comprises a pattern of a feature in the generated image.

11. The system of claim 10, wherein generating the calibrated frequency, magnitude, and phase of the image disturbance comprises characterizing the pattern.

12. The system of claim 10, wherein the pattern is periodic.

13. The system of claim 9, wherein manipulating charged particles to scan the sample reduces image disturbance caused by the power input.

14. The system of claim 9, wherein the first disturbance data comprises a magnitude and a phase of an image disturbance in a first direction and the second disturbance data comprises a magnitude and a phase of an image disturbance in a second direction.

15. The system of claim 14, wherein the compensation signal comprises image coordinates of the generated image in the first direction and image coordinates of the generated image in the second direction, wherein the image coordinates of the generated image lack coordinates for controlling the plurality of deflection drivers.

16. A non-transitory computer readable medium including a set of instructions that is executable by one or more processors of an apparatus to cause the apparatus to perform a method comprising:
generating a reference signal based on a power input for an imaging system;
generating a scan signal indicating a scan of a sample;
extracting, from an image generated from the scan, a frequency profile of an image disturbance;
generating a calibrated signal based on the reference signal and the extracted frequency profile;
generating a compensation signal using the calibrated signal and the reference signal;
transforming image coordinates associated with the compensation signal into deflection driver coordinates; and
using the deflection driver coordinates of the compensation signal to control a plurality of deflection drivers used for manipulating charged particles to scan the sample.

17. The non-transitory computer readable medium of claim 16, wherein the image disturbance comprises a pattern of a feature in the generated image.

18. The non-transitory computer readable medium of claim 17, wherein generating the calibrated signal comprises characterizing the pattern.

19. The non-transitory computer readable medium of claim 17, wherein the pattern is periodic.

20. The non-transitory computer readable medium of claim 16, wherein manipulating charged particles to scan the sample reduces image disturbance caused by the power input.
